(19) United States
(12) Patent Application Publication
(10) Pub. No.: US 2024/0403526 A1
(43) Pub. Date: Dec. 5, 2024

(54) INTEGRATED CIRCUIT DESIGN VERIFICATION WITH MODULE SWAPPING

(71) Applicant: SiFive, Inc., Santa Clara, CA (US)

(72) Inventors: Adam Moshe Izraelevitz, San Mateo, CA (US); Albert Pengju Chen, San mateo, CA (US)

(73) Assignee: SiFive, Inc., Santa Clara, CA (US)

(21) Appl. No.: 18/805,453

(22) Filed: Aug. 14, 2024

Related U.S. Application Data
(63) Continuation of application No. PCT/US2023/010557, filed on Jan. 11, 2023.
(60) Provisional application No. 63/311,543, filed on Feb. 18, 2022.

(51) Int. Cl. G06F 30/3308

(52) U.S. Cl. CPC G06F 30/3308

(57) ABSTRACT

An integrated circuit design may be generated for an integrated circuit. The integrated circuit design may include an instance of a module description that describes a functional operation of a module. The instance may include an input and an output. The integrated circuit design may be encoded in an intermediate representation (IR) data structure. Parameters may be received indicating that the instance should be replaced with a simulation model. The parameters may include a first parameter pointing to the instance and a second parameter pointing to the simulation model.

### CROSS-REFERENCES TO RELATED APPLICATIONS

This application is a continuation of International Application No. PCT/US2023/010557, filed Jan. 11, 2023, which claims priority to U.S. Provisional Application No. 63/311,543, filed Feb. 18, 2022, the entire contents of which are incorporated herein by reference for all purposes.

### FIELD OF TECHNOLOGY

This disclosure relates generally to integrated circuit design and, more specifically, to integrated circuit design verification with module swapping.

### BACKGROUND

Integrated circuits may be designed and tested in a multi-step process that involves multiple specialized engineers performing a variety of different design and verification tasks on an integrated circuit design. A variety of integrated circuit design tool chains may be used by these engineers to handle different parts of the integrated circuit design workflow of using commercial electronic design automation (EDA) tools.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a block diagram of an example of a system for facilitating generation and manufacture of integrated circuits.

FIG. 2 is a block diagram of an example of a system for facilitating generation of integrated circuits.

FIG. 3 is a block diagram of an example of a system for replacing an instance of a module description with a simulation model.

FIG. 4 is a block diagram of another example of a system for replacing an instance of a module description with a simulation model.

FIG. 5 is a block diagram of an example of a system including an integrated circuit design with instances of module descriptions.

FIG. 6 is a block diagram of an example of a system including an integrated circuit design in which an instance of a module description is selected for replacement by a simulation model.

FIG. 7 is flow chart of a process for replacing an instance of a module description with a simulation model.

FIG. 8 is flow chart of another process for replacing an instance of a module description with a simulation model

### DETAILED DESCRIPTION

Automated generation of integrated circuit designs permits a configuration of an application specific integrated circuit (ASIC) or a system on a chip (SoC) to be specified in terms of design parameters (or colloquially knobs). A system may then automate the operation of commercial electronic design automation (EDA) tools for design of the integrated circuit using the design parameters.

For example, a system may execute an integrated circuit generator (or simply a generator) to access design parameters and generate an integrated circuit design. In some implementations, the generator may use a hardware description language (HDL) embedded in a general-purpose programming language (e.g., Scala) that supports object-oriented programming and/or functional programming. For example, Chisel, an open source HDL embedded in Scala, a statically typed general purpose programming language that supports both object-oriented programming and functional programming, may be used to generate an integrated circuit design. The generator may include module descriptions that specify input(s), output(s), and/or a description(s) of a functional operation of a module (e.g., a processor core, cache, or the like, which may be represented, for example, by a Scala class).

In a process referred to as elaboration, the generator may execute to generate an integrated circuit design based on the design parameters. The integrated circuit design may include instances of module descriptions with connections being made. For example, the generator may execute constructor code to establish instances of Scala classes, with wired connections between them, as an instantiation of an integrated circuit design. In some implementations, the integrated circuit design may be encoded in an intermediate representation (IR) data structure. The IR data structure may be configured for optimization and/or translation by a compiler to produce a register-transfer level (RTL) data structure. For example, the generator may generate the integrated circuit design as a flexible intermediate representation for register-transfer level (FIRRTL) data structure. The FIRRTL data structure may be compiled by a FIRRTL compiler to produce an RTL data structure.

In a process referred to as compilation, the elaborated integrated circuit design (e.g., the IR data structure) may be compiled to generate an RTL data structure. For example, compiling the integrated circuit design may comprise executing one or more lowering transformations (e.g., compiler transformations that remove high-level constructs) to transform the integrated circuit design to generate the RTL data structure. The RTL data structure may encode a topology of logic associated with the instances of module descriptions implemented in the integrated circuit design (e.g., logic descriptions of the modules, such as the processor cores, caches, and the like). The RTL data structure may be compatible with EDA tools that may be used for functional verification (e.g., simulation analysis), synthesis (e.g., conversion to a gate-level description), placement and routing (e.g., physical design), and/or manufacturing of an integrated circuit (e.g., a processor, a microcontroller, an ASIC, or an SoC). In some implementations, the RTL data structure may comprise Verilog. For example, the integrated circuit design may be compiled using a FIRRTL compiler to generate Verilog.

During the design process, it may be useful to verify (e.g., test) logic descriptions associated with one or more modules implemented in the RTL data structure, such as one of the processor cores or caches. One technique for testing logic descriptions is to replace a logic description in the RTL data structure (e.g., associated with the design) with a simulation model. A simulation model may comprise software that simulates the operation of hardware in a predetermined manner, e.g., providing specific inputs and/or outputs. A simulation model may also be simplified over a logic description associated with the design. For example, to verify a logic description associated with a private level 2 (L2) cache, a logic description associated with a processor core in communication with the L2 cache may be replaced with a simulation model (e.g., a bus functional model, such as a traffic generator). The simulation model may be configured to send a specific traffic pattern to the logic description associated with the L2 cache. Using the simulation model may permit testing the logic description associated with the L2 cache with improved coverage of corner cases, such as by controlling the behavior of the model (e.g., controlling the software associated with the processor core to send a particular pattern to the L2 cache). Using a simulation model may also permit faster testing, such as by simplifying the logic description associated with the processor core with the software associated with the simulation model.

Replacing a logic description in an RTL data structure with a simulation model may be a manual and/or time consuming process. For example, replacing a logic description with a simulation model may involve manually editing the RTL data structure in multiple locations to include connections to the simulation model (and/or preparing such connections to the simulation model in a separate configuration file). Further, when a change is made by the integrated circuit generator, the RTL data structure may become out of sync with the integrated circuit design that is produced by the generator. As a result, the integrated circuit design may be compiled again, which may involve manually editing the RTL data structure again. Accordingly, there is a need to permit testing of logic descriptions in an RTL data structure in a way that improves efficiency and/or keeps the design and simulation processes in sync

Described herein are techniques which permit testing of logic descriptions in an RTL data structure (e.g., simulation). An integrated circuit generator may be used to generate an integrated circuit design including instances of module descriptions. A module description may specify input(s), output(s), and/or a description(s) of a functional operation of a module (e.g., a processor core, cache, or the like, which may be represented, for example, by a Scala class). Instances of module descriptions may include input(s) and/or output(s). The generator (e.g., Chisel) may use an HDL embedded in a general-purpose programming language (e.g., Scala) to generate the integrated circuit design. The integrated circuit design may be encoded in an IR data structure. A control interface, such as an application program interface (API), may receive parameters indicating that an instance in the integrated circuit design should be replaced (e.g., substituted or swapped) with a simulation model. The parameters may include a first parameter pointing to the instance in the integrated circuit design (e.g., to be replaced) and a second parameter pointing to the simulation model (e.g., to be used for the replacement).

In some implementations, the parameters may be used to generate an annotation for a compiler that is used to compile the integrated circuit design to generate an RTL data structure. For example, the parameters may be used to generate an annotation for a FIRRTL compiler that is used to compile the integrated circuit design to generate Verilog. The annotation may be used to build and/or modify one or more transformations that are used by the compiler.

In some implementations, the compiler may use the annotation to generate the RTL data structure with a logic description associated with the instance being replaced by a logic description associated with the simulation model. A simulator that does not natively support model substitutions (e.g., Verilator) may then simulate the RTL data structure with the logic description associated with the simulation model in the RTL data structure.

In some implementations, the compiler may use the annotation to generate instructions (e.g., a configuration file) for a simulator to replace a logic description associated with the instance with a logic description associated with the simulation model. A simulator that natively supports model substitutions (e.g., Synopsys VCS®) may then use the instructions to substitute the logic description associated with the instance with the logic description associated with the simulation model when simulating the RTL data structure. In some implementations, the instructions may comprise Verilog.

As a result, an instance of a module description in an integrated circuit design may be programmatically selected for replacement by a simulation model (e.g., a user may walk the instance hierarchy in the design and select the instance to be replaced with a model). The control interface and the compiler may facilitate the substitution of the instance with the simulation model. This may improve the efficiency of testing by a simulator and/or may keep the design and simulation processes in sync.

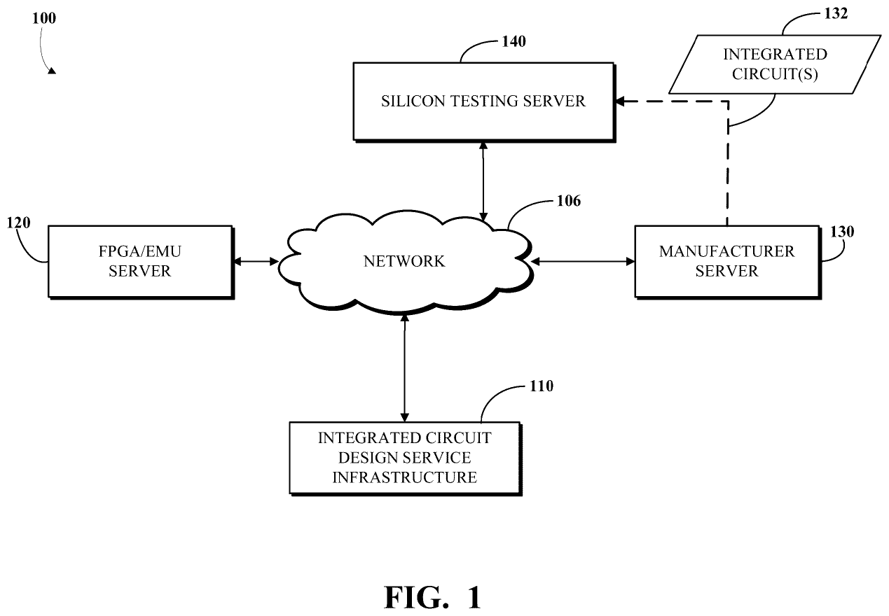

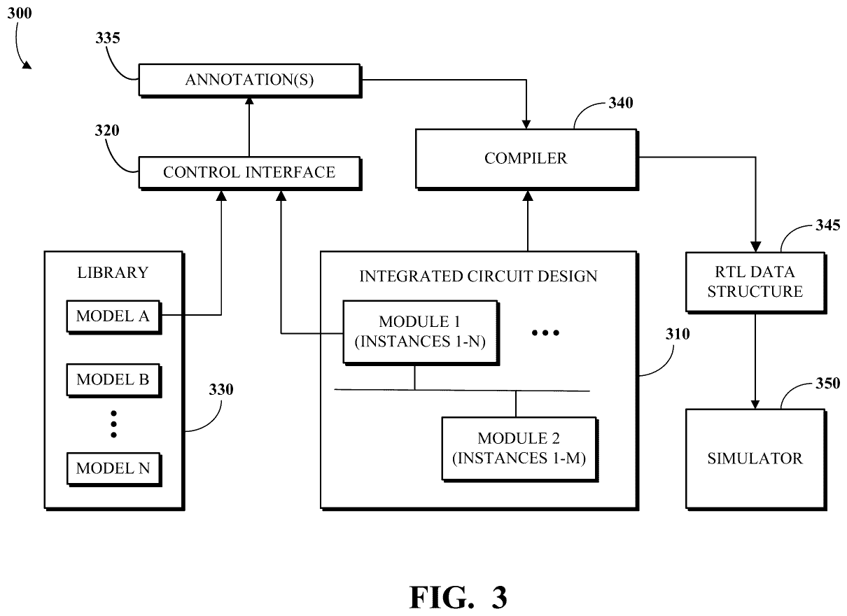

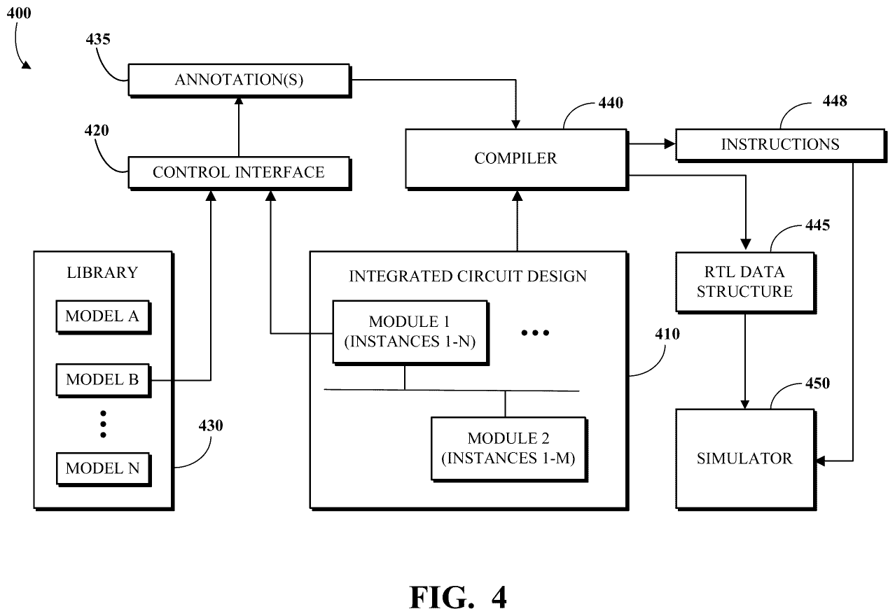

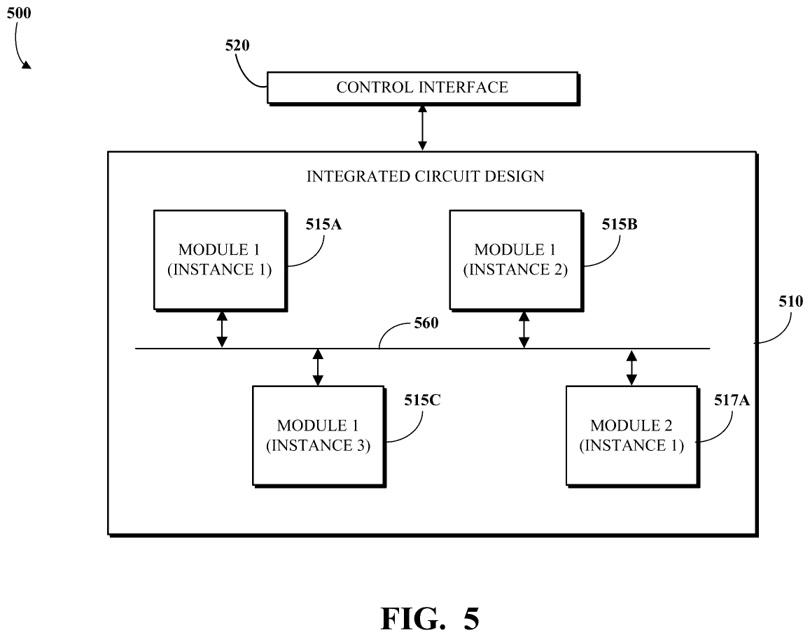

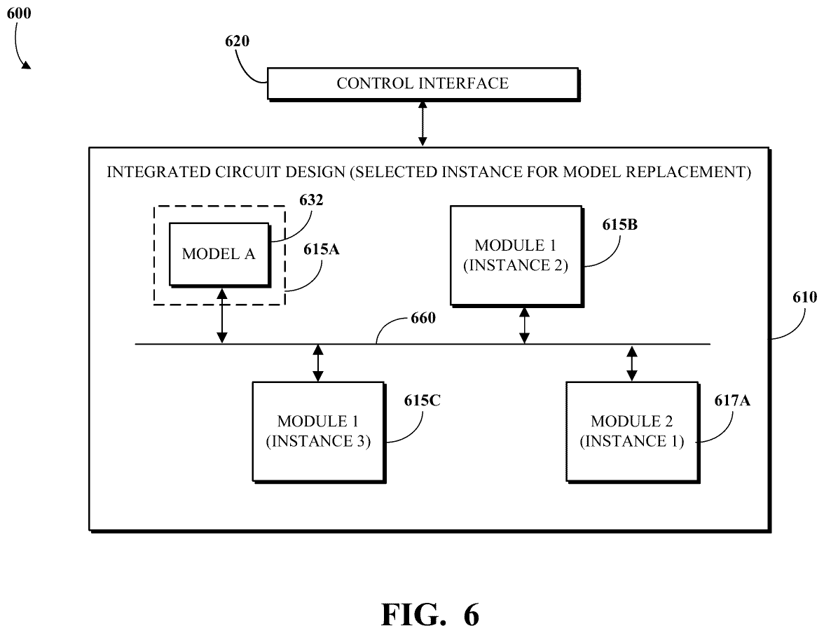

FIG. 1 is a block diagram of an example of a system 100 for generation and manufacture of integrated circuits. The system 100 includes a network 106, an integrated circuit design service infrastructure 110 (e.g., integrated circuit generator), a field programmable gate array (FPGA)/emulator server 120, and a manufacturer server 130. For example, a user may utilize a web client or a scripting application program interface (API) client to command the integrated circuit design service infrastructure 110 to automatically generate an integrated circuit design based on a set of design parameter values selected by the user for one or more template integrated circuit designs. In some implementations, the integrated circuit design service infrastructure 110 may be configured to generate an integrated circuit design like the integrated circuit design 310 shown in FIG. 3, the integrated circuit design 410 shown in FIG. 4, the integrated circuit design 510 shown in FIG. 5, and/or the integrated circuit design 610 shown in FIG. 6.

The integrated circuit design service infrastructure 110 may include a register-transfer level (RTL) service module configured to generate an RTL data structure for the integrated circuit based on a design parameters data structure. For example, the RTL service module may be implemented as Scala code. For example, the RTL service module may be implemented using Chisel. For example, the RTL service module may be implemented using flexible intermediate representation for register-transfer level (FIRRTL) and/or a FIRRTL compiler. For example, the RTL service module may be implemented using Diplomacy. For example, the RTL service module may enable a well-designed chip to be automatically developed from a high level set of configuration settings using a mix of Diplomacy, Chisel, and FIRRTL. The RTL service module may take the design parameters data structure (e.g., a java script object notation (JSON) file) as input and output an RTL data structure (e.g., a Verilog file) for the chip.

In some implementations, the integrated circuit design service infrastructure 110 may invoke (e.g., via network communications over the network 106) testing of the resulting design that is performed by the FPGA/emulation server 120 that is running one or more FPGAs or other types of hardware or software emulators. For example, the integrated circuit design service infrastructure 110 may invoke a test using a field programmable gate array, programmed based on a field programmable gate array emulation data structure, to obtain an emulation result. The field programmable gate array may be operating on the FPGA/emulation server 120, which may be a cloud server. Test results may be returned by the FPGA/emulation server 120 to the integrated circuit design service infrastructure 110 and relayed in a useful format to the user (e.g., via a web client or a scripting API client).

The integrated circuit design service infrastructure 110 may also facilitate the manufacture of integrated circuits using the integrated circuit design in a manufacturing facility associated with the manufacturer server 130. In some implementations, a physical design specification (e.g., a graphic data system (GDS) file, such as a GDSII file) based on a physical design data structure for the integrated circuit is transmitted to the manufacturer server 130 to invoke manufacturing of the integrated circuit (e.g., using manufacturing equipment of the associated manufacturer). For example, the manufacturer server 130 may host a foundry tape-out website that is configured to receive physical design specifications (e.g., such as a GDSII file or an open artwork system interchange standard (OASIS) file) to schedule or otherwise facilitate fabrication of integrated circuits. In some implementations, the integrated circuit design service infrastructure 110 supports multi-tenancy to allow multiple integrated circuit designs (e.g., from one or more users) to share fixed costs of manufacturing (e.g., reticle/mask generation, and/or shuttles wafer tests). For example, the integrated circuit design service infrastructure 110 may use a fixed package (e.g., a quasi-standardized packaging) that is defined to reduce fixed costs and facilitate sharing of reticle/mask, wafer test, and other fixed manufacturing costs. For example, the physical design specification may include one or more physical designs from one or more respective physical design data structures in order to facilitate multi-tenancy manufacturing.

In response to the transmission of the physical design specification, the manufacturer associated with the manufacturer server 130 may fabricate and/or test integrated circuits based on the integrated circuit design. For example, the associated manufacturer (e.g., a foundry) may perform optical proximity correction (OPC) and similar post-tape-out/pre-production processing, fabricate the integrated circuit(s) 132, update the integrated circuit design service infrastructure 110 (e.g., via communications with a controller or a web application server) periodically or asynchronously on the status of the manufacturing process, perform appropriate testing (e.g., wafer testing), and send to a packaging house for packaging. A packaging house may receive the finished wafers or dice from the manufacturer and test materials and update the integrated circuit design service infrastructure 110 on the status of the packaging and delivery process periodically or asynchronously. In some implementations, status updates may be relayed to the user when the user checks in using the web interface, and/or the controller might email the user that updates are available.

In some implementations, the resulting integrated circuit(s) 132 (e.g., physical chips) are delivered (e.g., via mail) to a silicon testing service provider associated with a silicon testing server 140. In some implementations, the resulting integrated circuit(s) 132 (e.g., physical chips) are installed in a system controlled by the silicon testing server 140 (e.g., a cloud server), making them quickly accessible to be run and tested remotely using network communications to control the operation of the integrated circuit(s) 132. For example, a login to the silicon testing server 140 controlling a manufactured integrated circuit(s) 132 may be sent to the integrated circuit design service infrastructure 110 and relayed to a user (e.g., via a web client). For example, the integrated circuit design service infrastructure 110 may be used to control testing of one or more integrated circuit(s) 132.

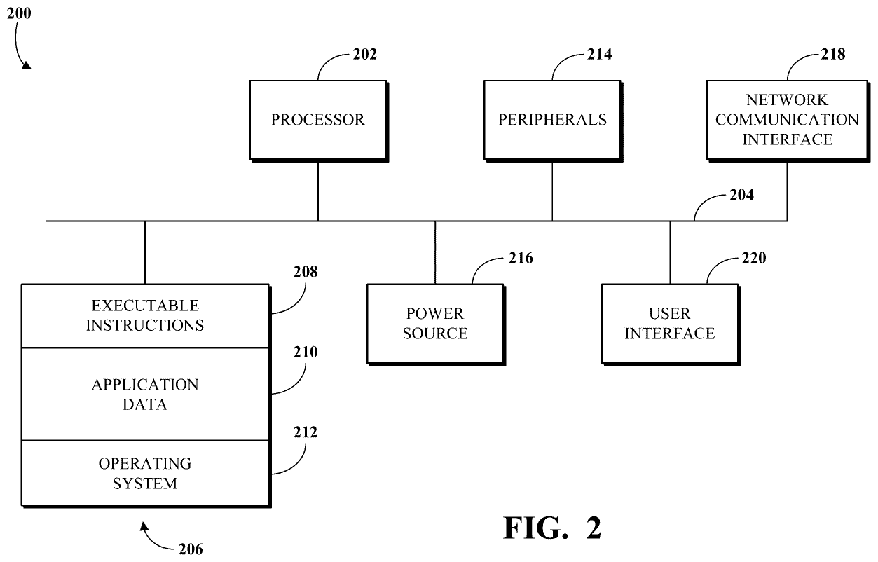

FIG. 2 is a block diagram of an example of a system 200 for facilitating generation of integrated circuits, for facilitating generation of a circuit representation for an integrated circuit, and/or for programming or manufacturing an integrated circuit. The system 200 is an example of an internal configuration of a computing device that may be used to implement the integrated circuit design service infrastructure 110, and/or to generate a file that generates a circuit representation of an integrated circuit design like the integrated circuit design 310 shown in FIG. 3, the integrated circuit design 410 shown in FIG. 4, the integrated circuit design 510 shown in FIG. 5, and/or the integrated circuit design 610 shown in FIG. 6. The system 200 can include components or units, such as a processor 202, a bus 204, a memory 206, peripherals 214, a power source 216, a network communication interface 218, a user interface 220, other suitable components, or a combination thereof.

The processor 202 can be a central processing unit (CPU), such as a microprocessor, and can include single or multiple processors having single or multiple processing cores. Alternatively, the processor 202 can include another type of device, or multiple devices, now existing or hereafter developed, capable of manipulating or processing information. For example, the processor 202 can include multiple processors interconnected in any manner, including hardwired or networked, including wirelessly networked. In some implementations, the operations of the processor 202 can be distributed across multiple physical devices or units that can be coupled directly or across a local area or other suitable type of network. In some implementations, the processor 202 can include a cache, or cache memory, for local storage of operating data or instructions.

The memory 206 can include volatile memory, non-volatile memory, or a combination thereof. For example, the memory 206 can include volatile memory, such as one or more dynamic random access memory (DRAM) modules such as double data rate (DDR) synchronous DRAM (SDRAM), and non-volatile memory, such as a disk drive, a solid-state drive, flash memory, Phase-Change Memory (PCM), or any form of non-volatile memory capable of persistent electronic information storage, such as in the absence of an active power supply. The memory 206 can include another type of device, or multiple devices, now existing or hereafter developed, capable of storing data or instructions for processing by the processor 202. The processor 202 can access or manipulate data in the memory 206 via the bus 204. Although shown as a single block in FIG. 2, the memory 206 can be implemented as multiple units. For example, a system 200 can include volatile memory, such as random access memory (RAM), and persistent memory, such as a hard drive or other storage.

The memory 206 can include executable instructions 208, data, such as application data 210, an operating system 212, or a combination thereof, for immediate access by the processor 202. The executable instructions 208 can include, for example, one or more application programs, which can be loaded or copied, in whole or in part, from non-volatile memory to volatile memory to be executed by the processor 202. The executable instructions 208 can be organized into programmable modules or algorithms, functional programs, codes, code segments, or combinations thereof to perform various functions described herein. For example, the executable instructions 208 can include instructions executable by the processor 202 to cause the system 200 to automatically, in response to a command, generate an integrated circuit design and associated test results based on a design parameters data structure. The application data 210 can include, for example, user files, database catalogs or dictionaries, configuration information or functional programs, such as a web browser, a web server, a database server, or a combination thereof. The operating system 212 can be, for example, Microsoft Windows®, macOS®, or Linux®; an operating system for a small device, such as a smartphone or tablet device; or an operating system for a large device, such as a mainframe computer. The memory 206 can comprise one or more devices and can utilize one or more types of storage, such as solid-state or magnetic storage.

The peripherals 214 can be coupled to the processor 202 via the bus 204. The peripherals 214 can be sensors or detectors, or devices containing any number of sensors or detectors, which can monitor the system 200 itself or the environment around the system 200. For example, a system 200 can contain a temperature sensor for measuring temperatures of components of the system 200, such as the processor 202. Other sensors or detectors can be used with the system 200, as can be contemplated. In some implementations, the power source 216 can be a battery, and the system 200 can operate independently of an external power distribution system. Any of the components of the system 200, such as the peripherals 214 or the power source 216, can communicate with the processor 202 via the bus 204.

The network communication interface 218 can also be coupled to the processor 202 via the bus 204. In some implementations, the network communication interface 218 can comprise one or more transceivers. The network communication interface 218 can, for example, provide a connection or link to a network, such as the network 106 shown in FIG. 1, via a network interface, which can be a wired network interface, such as Ethernet, or a wireless network interface. For example, the system 200 can communicate with other devices via the network communication interface 218 and the network interface using one or more network protocols, such as Ethernet, transmission control protocol (TCP), Internet protocol (IP), power line communication (PLC), Wi-Fi, infrared, general packet radio service (GPRS), global system for mobile communications (GSM), code division multiple access (CDMA), or other suitable protocols.

A user interface 220 can include a display; a positional input device, such as a mouse, touchpad, touchscreen, or the like; a keyboard; or other suitable human or machine interface devices. The user interface 220 can be coupled to the processor 202 via the bus 204. Other interface devices that permit a user to program or otherwise use the system 200 can be provided in addition to or as an alternative to a display. In some implementations, the user interface 220 can include a display, which can be a liquid crystal display (LCD), a cathode-ray tube (CRT), a light emitting diode (LED) display (e.g., an organic light emitting diode (OLED) display), or other suitable display. In some implementations, a client or server can omit the peripherals 214. The operations of the processor 202 can be distributed across multiple clients or servers, which can be coupled directly or across a local area or other suitable type of network. The memory 206 can be distributed across multiple clients or servers, such as network-based memory or memory in multiple clients or servers performing the operations of clients or servers. Although depicted here as a single bus, the bus 204 can be composed of multiple buses, which can be connected to one another through various bridges, controllers, or adapters.

A non-transitory computer readable medium may store a circuit representation that, when processed by a computer, is used to program or manufacture an integrated circuit. For example, the circuit representation may describe the integrated circuit specified using a computer readable syntax. The computer readable syntax may specify the structure or function of the integrated circuit or a combination thereof. In some implementations, the circuit representation may take the form of a hardware description language (HDL) program, a register-transfer level (RTL) data structure, a flexible intermediate representation for register-transfer level (FIRRTL) data structure, a Graphic Design System II (GDSII) data structure, a netlist, or a combination thereof. In some implementations, the integrated circuit may take the form of a field programmable gate array (FPGA), application specific integrated circuit (ASIC), system-on-a-chip (SoC), or some combination thereof. A computer may process the circuit representation in order to program or manufacture an integrated circuit, which may include programming a field programmable gate array (FPGA) or manufacturing an application specific integrated circuit (ASIC) or a system on a chip (SoC). In some implementations, the circuit representation may comprise a file that, when processed by a computer, may generate a new description of the integrated circuit. For example, the circuit representation could be written in a language such as Chisel, an HDL embedded in Scala, a statically typed general purpose programming language that supports both object-oriented programming and functional programming.

In an example, a circuit representation may be a Chisel language program which may be executed by the computer to produce a circuit representation expressed in a FIRRTL data structure. In some implementations, a design flow of processing steps may be utilized to process the circuit representation into one or more intermediate circuit representations followed by a final circuit representation which is then used to program or manufacture an integrated circuit. In one example, a circuit representation in the form of a Chisel program may be stored on a non-transitory computer readable medium and may be processed by a computer to produce a FIRRTL circuit representation. The FIRRTL circuit representation may be processed by a computer to produce an RTL circuit representation. The RTL circuit representation may be processed by the computer to produce a netlist circuit representation. The netlist circuit representation may be processed by the computer to produce a GDSII circuit representation. The GDSII circuit representation may be processed by the computer to produce the integrated circuit.

In another example, a circuit representation in the form of Verilog or VHDL may be stored on a non-transitory computer readable medium and may be processed by a computer to produce an RTL circuit representation. The RTL circuit representation may be processed by the computer to produce a netlist circuit representation. The netlist circuit representation may be processed by the computer to produce a GDSII circuit representation. The GDSII circuit representation may be processed by the computer to produce the integrated circuit. The foregoing steps may be executed by the same computer, different computers, or some combination thereof, depending on the implementation.

FIG. 3 is a block diagram of an example of a system 300 for replacing an instance of a module description with a simulation model. The system 300 may include an integrated circuit design 310, a control interface 320, a library 330, a compiler 340, and a simulator 350. An integrated circuit generator may be used to generate the integrated circuit design 310. For example, the integrated circuit design service infrastructure 110 shown in FIG. 1 may be used to generate the integrated circuit design 310. The generator may use an HDL embedded in a general-purpose programming language (e.g., Scala) that supports object-oriented programming and/or functional programming. For example, Chisel, an open source HDL embedded in Scala, a statically typed general purpose programming language that supports both object-oriented programming and functional programming, may be used to generate the integrated circuit design 310. For example, the integrated circuit design 310 may be encoded in an intermediate representation (IR) data structure (e.g., a FIRRTL data structure).

The integrated circuit design 310 may include module descriptions. A module description may describe a functional operation of a module (e.g., a processor core or a cache). The integrated circuit design 310 may be executed so that it is elaborated (e.g., expanded) to include instances of the module descriptions. For example, the integrated circuit design 310 may be expanded to include instances 1 through N of module description 1, and instances 1 through M of module description 2. The module descriptions can be manipulated using functions of a general-purpose programming language (e.g., embedded in Scala). Interfaces to the module descriptions can be encoded in types associated with the general-purpose programming language.

An instance of a module description may include input(s) and/or output(s) and may be representative of hardware to be implemented in the integrated circuit design (e.g., the processor core or the cache). For example, module description 1 may correspond to a processor core, and instances 1 through N of module description 1 may correspond to N instances of the processor core. Additionally, module description 2 may correspond to a cache, and instances 1 through M of module description 2 may correspond to M instances of the cache. Additionally, one or more of the instances may be configured to be in communication with one another, such via a system bus.

The control interface 320 may execute in the system 300 to receive parameters that indicate replacing a first instance of a module description (in the integrated circuit design 310) with a simulation model. For example, the control interface 320 may be an API executing in the system 300. The control interface 320 may receive a first parameter pointing to the first instance in the integrated circuit design 310 to be replaced and a second parameter pointing to the simulation model to be used for the replacement. For example, the control interface 320 may receive a first parameter pointing to instance 1 of module description 1 in the integrated circuit design 310 (e.g., to be replaced) and a second parameter pointing to simulation model A in the library 330 (e.g., to be used for the replacement of instance 1 of module description 1). The simulation model may comprise software that simulates the operation of hardware in a predetermined manner, e.g., providing specific inputs and/or outputs. The simulation model may also be simplified over software that describes the instance that is being replaced. For example, simulation model A may comprise software that simulates the operation of hardware represented by instance 1 of module description 1 (e.g., a processor core). Additionally, simulation model A may be simplified over software that describes logic associated with instance 1 of module description 1 (e.g., the processor core). In some implementations, the parameters may specify multiple instances to be replaced by one or more simulation models.

The control interface 320 may further execute in the system 300 to generate one or more compiler annotations 335 for the compiler 340. The annotations 335 may be based on the parameters. The annotations 335 may be used to build and/or modify one or more transformations that are executed by the compiler 340. In some implementations, the annotations 335 may comprise one or more strings in a serialized data format. The compiler 340 may compile the integrated circuit design 310 (e.g., execute the transformations, based on the annotations 335) to generate the RTL data structure 345 with a logic description associated with the first instance being replaced by a logic description associated with the simulation model in the RTL data structure 345. For example, the compiler 340 may compile the integrated circuit design 310 to generate the RTL data structure 345 with a logic description associated with instance 1 of module description 1 being replaced by a logic description associated with simulation model A in the RTL data structure 345. In some implementations, the compiler 340 may be a FIRRTL compiler that compiles the integrated circuit design 310 to generate an RTL data structure. In some implementations, the compiler 340 compile the integrated circuit design 310 to generate an RTL data structure comprising Verilog. Following compilation, a logic description associated with the first instance may be replaced by a logic description associated with the simulation model in the RTL data structure 345. For example, a logic description associated with instance 1 of module description 1 may be replaced by a logic description associated with simulation model A (e.g., from the library 330) in the RTL data structure 345.

The simulator 350, which may be a simulator that does not natively support model substitutions (such as Verilator), may then simulate the RTL data structure 345 with the logic description associated with the first instance being replaced by the logic description associated with the simulation model in the RTL data structure 345. In other words, the RTL data structure 345 that is simulated by the simulator 350 may already have the logic description associated with the first instance replaced by a logic description associated the simulation model (e.g., based on the parameters). For example, the RTL data structure 345 that is simulated by the simulator 350 may have a logic description associated with instance 1 of module description 1 replaced by a logic description associated with simulation model A (e.g., from the library 330) in the RTL data structure 345.

The simulator 350 may then simulate the RTL data structure 345 to verify (e.g., test) logic in the design (such as a logic description associated with a second instance of the module description) with the benefit of certain logic being replaced by the simulation model. Using the simulation model may permit testing with improved coverage of corner cases, such as by controlling the behavior of the simulation model being used. Using the simulation model may also permit faster testing, such as by simplifying a logic description in the design with software associated with the simulation model. For example, the simulator 350 may simulate the RTL data structure 345 to verify logic associated with another instance of a module description. As a result, an instance of a module description (e.g., instance 1 of module description 1) in the integrated circuit design 310 may be programmatically selected for replacement by a simulation model (e.g., simulation model A). The control interface 320 and the compiler 340 may facilitate the replacement of the instance with the simulation model. This may improve the efficiency of testing by the simulator 350 and/or may keep the design and simulation processes in sync.

In some implementations, the simulation model may be used to simulate traffic over a system bus. In other words, the simulation model may be a bus functional model or traffic generator. For example, logic associated with the simulation model may be used to simulate a processor core generating traffic over a system bus. In some implementations, the simulation model may be used to simulate storing data and/or responding to memory requests over a system bus. For example, logic associated with the simulation model may be used to simulate a cache (e.g., a private L2 cache associated with a processor core, or a shared level 3 (L3) cache associated with multiple processor cores). In some implementations, the library 330 may include multiple simulation models that simulate different types of hardware. For example, simulation model A may be used to simulate a first type of processor core, simulation model B may be used to simulate a second type of processor core, simulation model C may be used to simulate a first type of cache, and so forth.

FIG. 4 is a block diagram of another example of a system 400 for replacing an instance of a module description with a simulation model. The system 400 may include an integrated circuit design 410, a control interface 420, a library 430, and a compiler 440, like the integrated circuit design 310, the control interface 320, the library 330, and the compiler 340, shown in FIG. 3, respectively. An integrated circuit generator may be used to generate the integrated circuit design 410. For example, the integrated circuit design service infrastructure 110 shown in FIG. 1 may be used to generate the integrated circuit design 410.

The control interface 420 may execute in the system 400 to receive parameters that indicate replacing a first instance of a module description (in the integrated circuit design 410) with a simulation model. For example, the control interface 420 may be an API executing in the system 400. The control interface 420 may receive a first parameter pointing to the first instance in the integrated circuit design 410 to be replaced and a second parameter pointing to the simulation model to be used for the replacement. For example, the control interface 420 may receive a first parameter pointing to instance 1 of module description 1 in the integrated circuit design 410 (e.g., to be replaced) and a second parameter pointing to simulation model B in the library 430 (e.g., to be used for the replacement of instance 1 of module description 1). In some implementations, the parameters may specify multiple instances to be replaced by one or more simulation models.

The control interface 420 may further execute in the system 400 to generate one or more compiler annotations 435 for the compiler 440. The annotations 435 may be based on the parameters. The annotations 435 may be used to build and/or modify one or more transformations that are executed by the compiler 440. In some implementations, the annotations 435 may comprise one or more strings in a serialized data format. The compiler 440 may generate instructions 448 (e.g., execute the transformations, based on the annotations 435) for the simulator 450 to replace a logic description associated with the first instance in the RTL data structure 445 with a logic description associated with the simulation model when simulating the RTL data structure 445. For example, the compiler 440 may generate a configuration file for the simulator. Additionally, the compiler 440 may compile the integrated circuit design 410 to generate the RTL data structure 445 (without replacing the logic description associated with the first instance with the logic description associated with the simulation model). For example, the compiler 440 may generate the RTL data structure 445 and the instructions 448 for the simulator 450 to replace a logic description associated with instance 1 of module description 1 with a logic description associated with simulation model B (e.g., from the library 430) when simulating the RTL data structure 445. In some implementations, the compiler 440 may be a FIRRTL compiler that generates the instructions 448 and compiles the integrated circuit design 410 to generate an RTL data structure. In some implementations, the compiler 440 may generate the instructions 448 and compile the integrated circuit design 410 to generate an RTL data structure comprising Verilog. In some implementations, the instructions 448 may comprise Verilog. Following compilation, a logic description associated with the first instance in the RTL data structure 445 may remain in the RTL data structure 445, and instructions may be emitted for the simulator 450 to replace the logic description associated with the first instance with a logic description associated with the simulation model.

The simulator 450, which may be a simulator that natively supports model substitutions (such as Synopsys VCS), may use the instructions 448 when simulating the RTL data structure 445. For example, the simulator 450 may use the instructions 448 to replace the logic description associated with instance 1 of module description 1 with a logic description associated with simulation model B when simulating the RTL data structure 445.

The simulator 450 may then simulate the RTL data structure 445, based on the instructions 448, to verify (e.g., test) logic in the design (such as a logic description associated with a second instance of the module description) with the benefit of certain logic being replaced by the simulation model. Using the simulation model may permit testing with improved coverage of corner cases by controlling the behavior of the simulation model being used. Using the simulation model may also permit faster testing, such as by simplifying a logic description in the design with software associated with the simulation model. For example, the simulator 450 may simulate the RTL data structure 445, based on the instructions 448, to verify logic associated with another instance of a module description. As a result, an instance of a module description (e.g., instance 1 of module description 1) in the integrated circuit design 410 may be programmatically selected for replacement by a simulation model (e.g., simulation model B). The control interface 420 and the compiler 440 may facilitate the replacement of the instance with the simulation model. This may improve the efficiency of testing by the simulator 450 and/or may keep the design and simulation processes in sync.

FIG. 5 is a block diagram of an example of a system 500 including an integrated circuit design 510 with instances of module descriptions. The system 500 may include the integrated circuit design 510 and a control interface 520 like the integrated circuit design 310 and the control interface 320 shown in FIG. 3 and/or the integrated circuit design 410 and the control interface 420 shown in FIG. 4. An integrated circuit generator may be used to generate the integrated circuit design 510. For example, the integrated circuit design service infrastructure 110 shown in FIG. 1 may be used to generate the integrated circuit design 510.

The integrated circuit design 510 may be elaborated (e.g., expanded) to include one or more instances of one or more module descriptions, such as instances 515A through 515C of a first module description, and instance 517A of a second module description. For example, instances 515A through 515C may be instances of a module description corresponding to a processor core (e.g., processor core 1, processor core 2, and processor core 3). For example, instance 517A may be an instance of a module description corresponding to a cache (e.g., an L3 cache shared by processor core 1, processor core 2, and processor core 3). The integrated circuit design 510 may be elaborated by executing the integrated circuit design 510. For example, the integrated circuit design 510 may be elaborated by executing Chisel. The integrated circuit design 510 may be encoded in IR data structure (e.g., a FIRRTL data structure). Further, the instances may include wired connections in the integrated circuit design 510, such as connections to a system bus 560. For example, instances 515A through 515C and instance 517A may be designed to communicate with one another via the system bus 560.

FIG. 6 is a block diagram of an example of a system 600 including an integrated circuit design 610 in which an instance of a module description is selected for replacement by a simulation model. The system 600 may include the integrated circuit design 610 and a control interface 620 like the integrated circuit design 510 and the control interface 520 shown in FIG. 5. An integrated circuit generator may be used to generate the integrated circuit design 610. For example, the integrated circuit design service infrastructure 110 shown in FIG. 1 may be used to generate the integrated circuit design 610.

The integrated circuit design 610 may be elaborated (e.g., expanded) to include one or more instances of one or more module descriptions, such as instances 615A through 615C of a first module description, and instance 617A of a second module description. For example, instances 615A through 615C may be instances of a module description corresponding to a processor core (e.g., processor core 1, processor core 2, and processor core 3). For example, instance 617A may be an instance of a module description corresponding to a cache (e.g., an L3 cache shared by processor core 1, processor core 2, and processor core 3). The integrated circuit design 610 may be elaborated by executing the integrated circuit design 610. The integrated circuit design 610 may be encoded in IR data structure (e.g., a FIRRTL data structure). For example, the integrated circuit design 610 may be elaborated by executing Chisel. Further, the instances may include wired connections in the integrated circuit design 610, such as connections to a system bus 660. For example, instances 615A through 615C and instance 617A may be designed to communicate with one another via the system bus 660.

The control interface 620, such as an application program interface (API), may receive parameters that indicate replacing an instance in the integrated circuit design 610 with a simulation model. For example, the control interface 620 may receive parameters that indicate replacing instance 615A in the integrated circuit design 610 with a simulation model 632. The parameters may be used to generate one or more annotations (e.g., the annotations 335 or the annotations 435) for a compiler (e.g., the compiler 340 or the compiler 440) to compile the integrated circuit design to generate an RTL data structure (e.g., the RTL data structure 345 or the RTL data structure 445) and/or instructions (e.g., the instructions 448) for a simulator. For example, the annotations may be used to build and/or modify one or more transformations that are used by the compiler. For example, the simulation model 632 may be a bus functional model (e.g., a traffic generator) configured to generate predetermined traffic patterns over the system bus 660, such as to test a logic description associated with instance 617A (e.g., a cache). As a result, an instance of a module description in an integrated circuit design may be programmatically selected for replacement by a simulation model, such as instance 615A being programmatically selected for replacement by simulation model 632. The control interface 620 and the compiler (e.g., the compiler 340 or the compiler 440) may facilitate the substitution of the instance with the simulation model. This may improve the efficiency of testing by a simulator and/or may keep the design and simulation processes in sync.

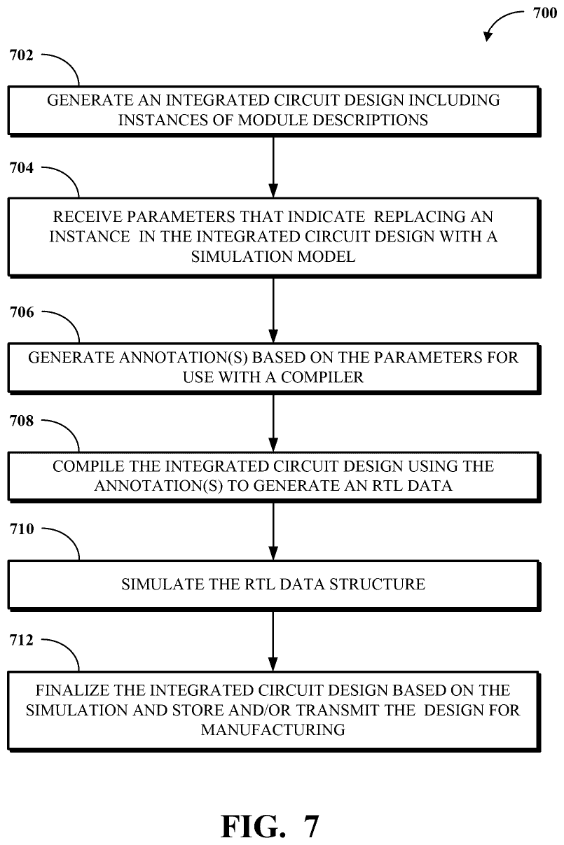

FIG. 7 is flow chart of a process 700 for replacing an instance of a module description with a simulation model. The process 700 includes generating 702 an integrated circuit design including instances of module descriptions; receiving 704 parameters that indicate replacing an instance in the integrated circuit design with a simulation model; generating 706 annotation(s) based on the parameters; compiling 708 the integrated circuit design using the annotation(s) to generate an RTL data structure that replaces the instance with the simulation model; simulating 710 the RTL data structure; and storing and/or transmitting 712 the integrated circuit design. For example, the process 700 may be implemented using the system 100 shown in FIG. 1, the system 200 shown in FIG. 2, the system 300 shown in FIG. 3, the system 400 shown in FIG. 4, the system 500 shown in FIG. 5, and/or the system 600 shown in FIG. 6.

The process 700 may include generating 702 an integrated circuit design (e.g., the integrated circuit design 310 or the integrated circuit design 410) including instances of module descriptions. For example, the integrated circuit design service infrastructure 110 shown in FIG. 1 may be used to generate the integrated circuit design. The generator may use an HDL embedded in a general-purpose programming language (e.g., Scala) that supports object-oriented programming and/or functional programming. For example, Chisel may be used to generate the integrated circuit design. The integrated circuit design may be encoded in an IR data structure (e.g., a FIRRTL data structure). The instances of module descriptions may be representative of hardware to be implemented in the integrated circuit design (e.g., processors cores, caches, and the like). The instances of module descriptions may include input(s) and/or output(s).

The process 700 may also include receiving 704 parameters that indicate replacing an instance in the integrated circuit design with a simulation model. For example, a control interface (e.g., the control interface 320 or the control interface 420) may execute to receive parameters that indicate replacing an instance of a module description (in the integrated circuit design) with a simulation model. In some implementations, the control interface may be an API executing in the system. The control interface may receive a first parameter pointing to the instance in the integrated circuit design to be replaced and a second parameter pointing to the simulation model to be used for the replacement. The simulation model may comprise software that simulates the operation of hardware in a predetermined manner, e.g., providing specific inputs and/or outputs. The simulation model may also be simplified over software that describes the logic description in the design that is being replaced. In some implementations, the parameters may specify multiple instances to be replaced by one or more simulation models.

The process 700 may also include generating 706 one or more compiler annotation(s) based on the parameters for use with a compiler (e.g., the compiler 340 or the compiler 440). For example, the control interface may further execute in the system to generate the one or more annotations for the compiler. The one or more annotations may be based on the parameters. The one or more annotations may be used to build and/or modify one or more transformations that are executed by the compiler. In some implementations, the one or more annotations may comprise one or more strings in a serialized data format. The one or more annotations may be configured to permit a compiler to replace a logic description associated with the instance with a logic description associated with the simulation model in the RTL data structure.

The process 700 may also include compiling 708 the integrated circuit design using the one or more annotations. The compiler may compile the integrated circuit design (e.g., execute the transformations, based on the one or more annotations) to generate the RTL data structure with the logic description associated with the instance being replaced by the logic description associated with the simulation model in the RTL data structure. In some implementations, the compiler may be a FIRRTL compiler that compiles the integrated circuit design (e.g., in FIRRTL) to generate an RTL data structure. In some implementations, the compiler may compile the integrated circuit design to generate an RTL data structure comprising Verilog. Following compilation, a logic description associated with the instance may be replaced by a logic description associated with the simulation model in the RTL data structure.

The process 700 may also include simulating 710 the RTL data structure to test a logic description associated with another instance of the integrated circuit design. For example, a simulator (such as Verilator), which might not natively support model substitutions, may simulate the RTL data structure with a logic description associated with the instance being replaced by a logic description associated with the simulation model (e.g., replaced by the compiler) in the RTL data structure. In other words, the RTL data structure that is simulated by the simulator may already have the logic description associated with the instance replaced by the logic description associated with the simulation model in the RTL data structure. The simulator may then simulate the RTL data structure to verify (e.g., test) logic in the design (such as a logic description associated with another instance in the design) with the benefit of certain logic being replaced by the simulation model.

The process 700 may also include storing and/or transmitting 712 the integrated circuit design. The integrated circuit design may be stored for use in subsequent steps, such as synthesis, placement and routing, implementation of clock trees, and/or simulation analysis. Additionally, the integrated circuit design may be transmitted for manufacturing of an integrated circuit, such as a SoC.

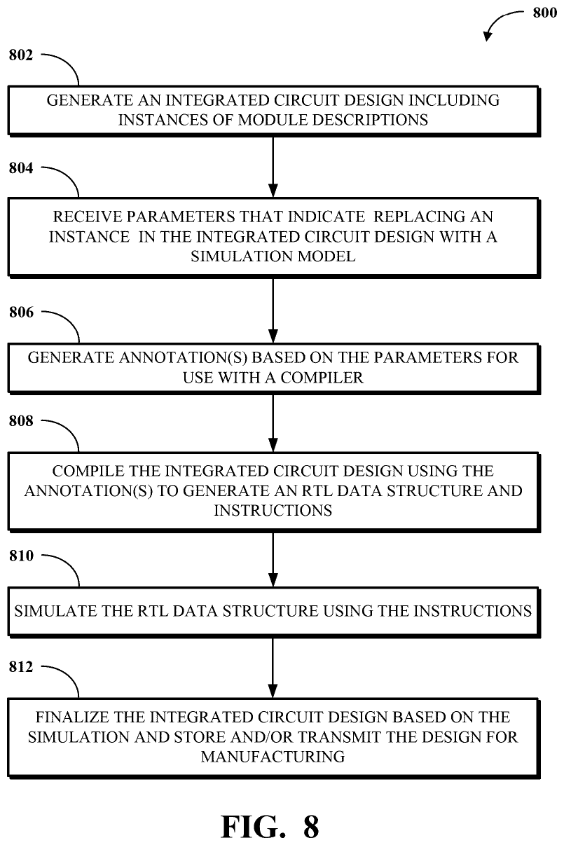

FIG. 8 is flow chart of a process 800 for replacing an instance of a module description with a simulation model. The process 800 includes generating 802 an integrated circuit design including instances of module descriptions; receiving 804 parameters that indicate replacing a first instance in the integrated circuit design with a simulation model; generating 806 annotation(s) based on the parameters; compiling 808 the integrated circuit design using the annotation(s) to generate an RTL data structure and instructions for replacing a logic description associated with the first instance with a logic description associated with the simulation model; simulating 810 the RTL data structure; and storing and/or transmitting 812 the integrated circuit design. For example, the process 800 may be implemented using the system 100 shown in FIG. 1, the system 200 shown in FIG. 2, the system 300 shown in FIG. 3, the system 400 shown in FIG. 4, the system 500 shown in FIG. 5, and/or the system 600 shown in FIG. 6.

The process 800 may include generating 802 an integrated circuit design (e.g., the integrated circuit design 310 or the integrated circuit design 410) including instances of module descriptions. For example, the integrated circuit design service infrastructure 110 shown in FIG. 1 may be used to generate the integrated circuit design. The generator may use an HDL embedded in a general-purpose programming language (e.g., Scala) that supports object-oriented programming and/or functional programming. For example, Chisel may be used to generate the integrated circuit design. The integrated circuit design may be encoded in an IR data structure (e.g., a FIRRTL data structure). The instances of module descriptions may be representative of hardware to be implemented in the integrated circuit design (e.g., processors cores, caches, and the like). The instances of module descriptions may include input(s) and/or output(s).

The process 800 may also include receiving 804 parameters that indicate replacing an instance in the integrated circuit design with a simulation model. For example, a control interface (e.g., the control interface 320 or the control interface 420) may execute to receive parameters that indicate replacing an instance of a module description (in the integrated circuit design) with a simulation model. In some implementations, the control interface may be an API executing in the system. The control interface may receive a first parameter pointing to the instance in the integrated circuit design to be replaced and a second parameter pointing to the simulation model to be used for the replacement. The simulation model may comprise software that simulates the operation of hardware in a predetermined manner, e.g., providing specific inputs and/or outputs. The simulation model may also be simplified over software that describes the logic description in the design that is being replaced. In some implementations, the parameters may specify multiple instances to be replaced by one or more simulation models.

The process 800 may also include generating 806 one or more compiler annotation(s) based on the parameters for use with a compiler (e.g., the compiler 340 or the compiler 440). For example, the control interface may further execute in the system to generate the one or more annotations for the compiler. The one or more annotations may be based on the parameters. The one or more annotations may be used to build and/or modify one or more transformations that are executed by the compiler. In some implementations, the one or more annotations may comprise one or more strings in a serialized data format. The one or more annotations may be configured to permit a compiler to generate instructions for a simulator to replace a logic description associated with the instance in an RTL data structure with a logic description associated with the simulation model when simulating the RTL data structure.

The process 800 may also include compiling 808 the integrated circuit design using the one or more annotations. The compiler may compile the integrated circuit design and generate instructions (e.g., execute the transformations, based on the one or more annotations) for the simulator to replace a logic description associated with the instance in the RTL data structure with a logic description associated with the simulation model when simulating the RTL data structure. In other words, the compiler may compile the integrated circuit design, to generate the RTL data structure, without replacing the logic description associated with the instance with the logic description associated with the simulation model. The compiler may generate the instructions so that the simulator can replace the logic description associated with the instance with the logic description associated with the simulation model when simulating the RTL data structure. In some implementations, the compiler may be a FIRRTL compiler that compiles the integrated circuit design (e.g., in FIRRTL) to generate an RTL data structure. In some implementations, the compiler may compile the integrated circuit design to generate an RTL data structure comprising Verilog.

The process 800 may also include simulating 810 the RTL data structure, with the instructions, to test a logic description associated with another instance of the integrated circuit design. For example, a simulator (such as Synopsys VCS), which may natively support model substitutions, may then use the instructions to simulate the RTL data structure. The simulator may use the instructions to replace a logic description associated with the instance with a logic description associated with the simulation model when simulating the RTL data structure. The simulator may then simulate the RTL data structure to verify (e.g., test) logic in the design (such as a logic description associated with another instance in the design) with the benefit of certain logic being replaced by the simulation model.

The process 800 may also include storing and/or transmitting 812 the integrated circuit design. The integrated circuit design may be stored for use in subsequent steps, such as synthesis, placement and routing, implementation of clock trees, and/or simulation analysis. Additionally, the integrated circuit design may be transmitted for manufacturing of an integrated circuit, such as a SoC.

In a first aspect, the subject matter described in this specification can be embodied in a method that includes: generating an integrated circuit design for an integrated circuit, wherein the integrated circuit design includes an instance of a module description that describes a functional operation of a module, wherein the instance includes an input and an output, and wherein the integrated circuit design is encoded in an intermediate representation (IR) data structure; and receiving parameters that indicate replacing the instance with a simulation model, wherein the parameters include a first parameter pointing to the instance and a second parameter pointing to the simulation model. In some implementations, the method may include generating an annotation based on the parameters for use by a compiler to compile the integrated circuit design with the instance replaced by the simulation model. In some implementations, the method may include compiling the integrated circuit design to generate a register-transfer level (RTL) data structure, wherein the RTL data structure includes a logic description associated with the simulation model. In some implementations, the instance is a first instance of the module description, and the method may include simulating the RTL data structure with the logic description associated with the simulation model to verify a logic description associated with a second instance of the module description. In some implementations, the IR data structure is a flexible intermediate representation for register-transfer level (FIRRTL) data structure, and the RTL data structure comprises Verilog. In some implementations, the method may include generating instructions for a simulator to simulate the integrated circuit design, wherein the instructions permit the simulator to replace a logic description associated with the instance with a logic description associated with the simulation model. In some implementations, the method may include compiling the integrated circuit design to generate an RTL data structure, wherein the RTL data structure includes a logic description associated with the instance; and using the instructions to simulate the RTL data structure, wherein the simulator replaces the logic description associated with the instance with the logic description associated with the simulation model. In some implementations, the simulation model is a bus functional model that simulates operation of the instance by generating traffic over a bus. In some implementations, the method may include selecting the simulation model from a library, wherein a first simulation model in the library simulates a processor core, and wherein a second simulation model in the library simulates a cache. In some implementations, the method may include executing an application program interface (API) to receive the parameters. In some implementations, the method may include executing a generator to generate the integrated circuit design, wherein the generator is configured using a general-purpose programming language.

In a second aspect, the subject matter described in this specification can be embodied in an apparatus that includes: a memory; and a processor configured to execute instructions stored in the memory to: generate an integrated circuit design for an integrated circuit, wherein the integrated circuit design includes an instance of a module description that describes a functional operation of a module, wherein the instance includes an input and an output, and wherein the integrated circuit design is encoded in an IR data structure; and receive parameters that indicate replacing the instance with a simulation model, wherein the parameters include a first parameter pointing to the instance and a second parameter pointing to the simulation model. In some implementations, the processor is further configured to execute instructions stored in the memory to generate an annotation based on the parameters for use by a compiler to compile the integrated circuit design with the instance replaced by the simulation model. In some implementations, the processor is further configured to execute instructions stored in the memory to compile the integrated circuit design to generate an RTL data structure, wherein the RTL data structure includes a logic description associated with the simulation model. In some implementations, the instance is a first instance of the module description, and the processor is further configured to execute instructions stored in the memory to simulate the RTL data structure with the logic description associated with the simulation model to verify a logic description associated with a second instance of the module description. In some implementations, the processor is further configured to generate instructions for a simulator to simulate the integrated circuit design, wherein the instructions permit the simulator to replace a logic description associated with the instance with a logic description associated with the simulation model.

In a third aspect, the subject matter described in this specification can be embodied in a non-transitory computer-readable storage medium that includes instructions that, when executed by a processor, causes the processor to: generate an integrated circuit design for an integrated circuit, wherein the integrated circuit design includes an instance of a module description that describes a functional operation of a module, wherein the instance includes an input and an output, and wherein the integrated circuit design is encoded in an IR data structure; and receive parameters that indicate replacing the instance with a simulation model, wherein the parameters include a first parameter pointing to the instance and a second parameter pointing to the simulation model. In some implementations, the instructions, when executed by the processor, further cause the processor to generate an annotation based on the parameters for use by a compiler to compile the integrated circuit design with the instance replaced by the simulation model. In some implementations, the instructions, when executed by the processor, further cause the processor to compile the integrated circuit design to generate an RTL data structure, wherein the RTL data structure includes a logic description associated with the simulation model. In some implementations, the instructions, when executed by the processor, further cause the processor to generate instructions for a simulator to simulate the integrated circuit design, wherein the instructions permit the simulator to replace a logic description associated with the instance with a logic description associated with the simulation model.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures.

What is claimed is:

1. A method comprising:
generating, by an integrated circuit generator executing on a computer system, an integrated circuit design for an integrated circuit, wherein the integrated circuit design includes an instance of a module description that describes a functional operation of a module, wherein the instance includes an input and an output, and wherein the integrated circuit design is encoded in an intermediate representation (IR) data structure;
receiving, by the integrated circuit generator, parameters that indicate replacing the instance with a simulation model, wherein the parameters include a first parameter pointing to the instance and a second parameter pointing to the simulation model; and
generating, by the integrated circuit generator, an annotation based on the parameters for use by a compiler to compile the integrated circuit design with the instance replaced by the simulation model.

2. The method of claim 1, further comprising:
compiling the integrated circuit design to generate a register-transfer level (RTL) data structure, wherein the RTL data structure includes a logic description associated with the simulation model.

3. The method of claim 2, wherein the instance is a first instance of the module description, and further comprising:
simulating the RTL data structure with the logic description associated with the simulation model to verify a logic description associated with a second instance of the module description.

4. The method of claim 2, wherein the IR data structure is a flexible intermediate representation for register-transfer level (FIRRTL) data structure, and wherein the RTL data structure comprises Verilog.

5. The method of claim 1, further comprising:
generating instructions for a simulator to simulate the integrated circuit design, wherein the instructions permit the simulator to replace a logic description associated with the instance with a logic description associated with the simulation model.

6. The method of claim 5, further comprising:
compiling the integrated circuit design to generate an RTL data structure, wherein the RTL data structure includes a logic description associated with the instance; and
using the instructions to simulate the RTL data structure, wherein the simulator replaces the logic description associated with the instance with the logic description associated with the simulation model.

7. The method of claim 1, wherein the simulation model is a bus functional model that simulates operation of the instance by generating traffic over a bus.

8. The method of claim 1, further comprising:
selecting the simulation model from a library, wherein a first simulation model in the library simulates a processor core, and wherein a second simulation model in the library simulates a cache.

9. The method of claim 1, further comprising:
executing an application program interface (API) to receive the parameters.

10. An apparatus, comprising:
a memory; and
a processor configured to execute instructions stored in the memory to:
generate an integrated circuit design for an integrated circuit, wherein the integrated circuit design includes an instance of a module description that describes a functional operation of a module, wherein the instance includes an input and an output, and wherein the integrated circuit design is encoded in an intermediate representation (IR) data structure;
receive parameters that indicate replacing the instance with a simulation model, wherein the parameters include a first parameter pointing to the instance and a second parameter pointing to the simulation model; and
generate an annotation based on the parameters for use by a compiler to compile the integrated circuit design with the instance replaced by the simulation model.

11. The apparatus of claim 10, wherein the processor is further configured to execute instructions stored in the memory to:
compile the integrated circuit design to generate an RTL data structure, wherein the RTL data structure includes a logic description associated with the simulation model.

12. The apparatus of claim 11, wherein the instance is a first instance of the module description, and wherein the processor is further configured to execute instructions stored in the memory to:
simulate the RTL data structure with the logic description associated with the simulation model to verify a logic description associated with a second instance of the module description.

13. The apparatus of claim 10, wherein the processor is further configured to execute instructions stored in the memory to:
generate instructions for a simulator to simulate the integrated circuit design, wherein the instructions permit the simulator to replace a logic description associated with the instance with a logic description associated with the simulation model.

14. The apparatus of claim 13, wherein the processor is further configured to execute instructions stored in the memory to:
compile the integrated circuit design to generate an RTL data structure, wherein the RTL data structure includes a logic description associated with the instance; and
use the instructions to simulate the RTL data structure, wherein the simulator replaces the logic description associated with the instance with the logic description associated with the simulation model.

15. The apparatus of claim 10, wherein the simulation model is a bus functional model that simulates operation of the instance by generating traffic over a bus.

16. The apparatus of claim 10, wherein the processor is further configured to execute instructions stored in the memory to:
select the simulation model from a library, wherein a first simulation model in the library simulates a processor core, and wherein a second simulation model in the library simulates a cache.

17. The apparatus of claim 10, wherein the processor is further configured to execute instructions stored in the memory to:
execute a generator to generate the integrated circuit design, wherein the generator is configured using a general-purpose programming language.

18. A non-transitory computer-readable storage medium that includes instructions that, when executed by a processor, causes the processor to:
generate an integrated circuit design for an integrated circuit, wherein the integrated circuit design includes an instance of a module description that describes a functional operation of a module, wherein the instance includes an input and an output, and wherein the integrated circuit design is encoded in an intermediate representation (IR) data structure;
receive parameters that indicate replacing the instance with a simulation model, wherein the parameters include a first parameter pointing to the instance and a second parameter pointing to the simulation model; and
generate an annotation based on the parameters for use by a compiler to compile the integrated circuit design with the instance replaced by the simulation model.

19. The non-transitory computer-readable storage medium of claim 18, wherein the instructions, when executed by the processor, further cause the processor to:
compile the integrated circuit design to generate an RTL data structure, wherein the RTL data structure includes a logic description associated with the simulation model.

20. The non-transitory computer-readable storage medium of claim 19, wherein the instance is a first instance of the module description, and wherein the instructions, when executed by the processor, further cause the processor to:
simulate the RTL data structure with the logic description associated with the simulation model to verify a logic description associated with a second instance of the module description.
